(19) United States
(12) Patent Application Publication
(10) Pub. No.: US 2019/0276931 A1
(43) Pub. Date: Sep. 12, 2019

(54) METHODS AND APPARATUS FOR PHYSICAL VAPOR DEPOSITION USING DIRECTIONAL LINEAR SCANNING

(71) Applicant: APPLIED MATERIALS, INC., Santa Clara, CA (US)

(72) Inventors: Bencherki Mebarki, SANTA CLARA, CA (US); Anantha K. Subramani, SAN JOSE, CA (US); Joung Joo Lee, SAN JOSE, CA (US); Farzad Houshmand, MOUNTAIN VIEW, CA (US); Kelvin Chan, SAN RAMON, CA (US); Kenneth Starks, Gloucester, MA (US); Xianmin Tang, SAN JOSE, CA (US)

(21) Appl. No.: 16/296,718

(22) Filed: Mar. 8, 2019

Related U.S. Application Data
(60) Provisional application No. 62/641,013, filed on Mar. 9, 2018.

(51) Int. Cl. C23C 14/54; H01L 21/02; H01L 21/285; C23C 14/50; C23C 14/34

(52) U.S. Cl. CPC C23C 14/54; H01L 21/02266; C23C 14/34; C23C 14/505; H01L 21/2855

(57) ABSTRACT

Methods and apparatus for physical vapor deposition are provided herein. In some embodiments, an apparatus for physical vapor deposition (PVD) includes: a linear PVD source to provide a stream of material flux comprising material to be deposited on a substrate; and a substrate support having a support surface to support the substrate at a non-perpendicular angle to the linear PVD source, wherein the substrate support and linear PVD source are movable with respect to each other along an axis that is perpendicular to a plane of the support surface of the substrate support sufficiently to cause the stream of material flux to move over a working surface of the substrate disposed on the substrate support during operation.

### CROSS-REFERENCE TO RELATED APPLICATIONS

This application claims benefit of U.S. provisional patent application Ser. No. 62/641,013, filed Mar. 9, 2018, which is herein incorporated by reference in its entirety.

### FIELD

Embodiments of the present disclosure generally relate to substrate processing equipment, and more particularly, to methods and apparatus for depositing materials via physical vapor deposition.

### BACKGROUND

The semiconductor processing industry generally continues to strive for increased uniformity of layers deposited on substrates. For example, with shrinking circuit sizes leading to higher integration of circuits per unit area of the substrate, increased uniformity is generally seen as desired, or required in some applications, in order to maintain satisfactory yields and reduce the cost of fabrication. Various technologies have been developed to deposit layers on substrates in a cost-effective and uniform manner, such as chemical vapor deposition (CVD) or physical vapor deposition (PVD).

However, the inventor has observed that with the drive to produce equipment to deposit more uniformly, certain applications may not be adequately served where purposeful deposition is required that is not symmetric or uniform with respect to the given structures being fabricated on a substrate.

Accordingly, the inventor has provided improved methods and apparatus for depositing materials via physical vapor deposition.

### SUMMARY

Methods and apparatus for physical vapor deposition are provided herein. In some embodiments, an apparatus for physical vapor deposition (PVD) includes: a linear PVD source to provide a stream of material flux comprising material to be deposited on a substrate; and a substrate support having a support surface to support the substrate at a non-perpendicular angle to the linear PVD source, wherein the substrate support and linear PVD source are movable with respect to each other along an axis that is perpendicular to a plane of the support surface of the substrate support sufficiently to cause the stream of material flux to move over a working surface of the substrate disposed on the substrate support during operation.

In accordance with at least some embodiments of the present disclosure, there is provided a method for physical vapor deposition (PVD). The method can include providing a stream of material flux comprising a first material to be deposited on a substrate using a linear PVD source; supporting the substrate at a non-perpendicular angle to the linear PVD source on a substrate support; and causing the stream of material flux to move over a working surface of the substrate by moving at least one of the substrate support or the linear PVD source along an axis perpendicular to a plane of the substrate to deposit the first material on the substrate.

In accordance with at least some embodiments of the present disclosure, there is provided a nontransitory computer readable storage medium having stored thereon instructions which when executed by a controller perform a method for physical vapor deposition (PVD). The method can include providing a stream of material flux comprising a first material to be deposited on a substrate using a linear PVD source; supporting the substrate at a non-perpendicular angle to the linear PVD source on a substrate support; and causing the stream of material flux to move over a working surface of the substrate by moving at least one of the substrate support or the linear PVD source along an axis perpendicular to a plane of the substrate to deposit the first material on the substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a schematic side view of an apparatus for physical vapor deposition in accordance with at least some embodiments of the present disclosure.

FIG. 2A is a schematic side view of a feature having a layer of material deposited thereon in accordance with at least some embodiments of the present disclosure.

FIG. 2B is a schematic side view of a substrate having a plurality of features having a layer of material deposited thereon, as depicted in FIG. 2A, in accordance with at least some embodiments of the present disclosure.

FIG. 2C is a schematic side view of a feature having a layer of material deposited thereon in accordance with at least some embodiments of the present disclosure.

FIG. 2D is a schematic side view of a substrate having a plurality of features having a layer of material deposited thereon, as depicted in FIG. 2C, in accordance with at least some embodiments of the present disclosure.

FIG. 3A is a schematic side view of an apparatus for physical vapor deposition in accordance with at least some embodiments of the present disclosure.

FIGS. 3B-3C respectively depict schematic top and isometric cross-sectional views of a substrate support and deposition structure of an apparatus for physical vapor deposition in accordance with at least some embodiments of the present disclosure.

FIG. 4 is a schematic side view of a portion of an apparatus for physical vapor deposition illustrating material deposition angles in accordance with at least some embodiments of the present disclosure.

FIG. 5 depicts schematic top and side views of an apparatus for physical vapor deposition illustrating material deposition angles in accordance with at least some embodiments of the present disclosure.

FIG. 6 depicts schematic top and side views of an apparatus for physical vapor deposition illustrating material deposition angles in accordance with at least some embodiments of the present disclosure.

FIG. 7 is a schematic side view of an apparatus for physical vapor deposition in accordance with at least some embodiments of the present disclosure.

FIG. 8 is a flowchart of a method for performing physical vapor deposition in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for physical vapor deposition (PVD) are provided herein. Embodiments of the disclosed methods and apparatus advantageously enable uniform angular deposition of materials on a substrate. In some applications, deposited materials are asymmetric or angular with respect to a given feature on a substrate, but can be relatively uniform within all features across the substrate. In some applications, deposited materials are symmetric with respect to a given feature on a substrate as well as relatively uniform within all features across the substrate, but possess a deposition profile not easily obtainable, if at all, using conventional physical vapor deposition techniques. Embodiments of the disclosed methods and apparatus advantageously enable new applications or opportunities for selective PVD of materials, thus further enabling new markets and capabilities.

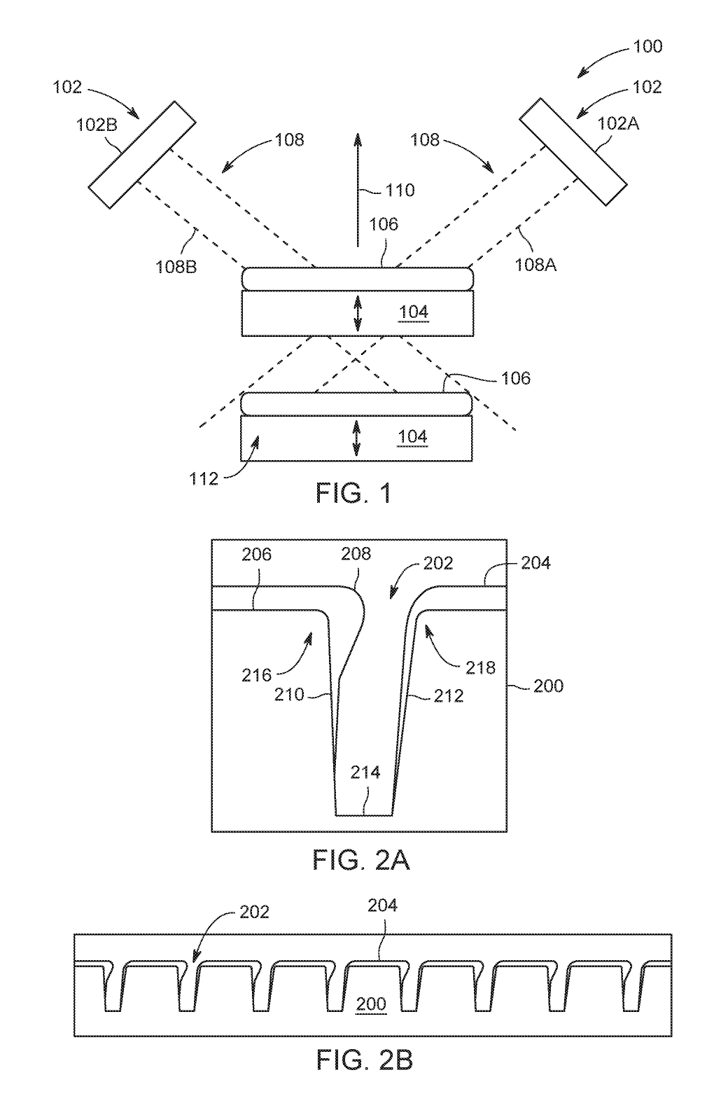

FIG. 1 is a schematic side view of an apparatus 100 for PVD in accordance with at least some embodiments of the present disclosure. Specifically, FIG. 1 schematically depicts an apparatus 100 for PVD of materials on a substrate at an angle to the generally planar surface of the substrate. The apparatus 100 generally includes a linear PVD source 102, or optionally including two opposing linear PVD sources 102A and 102B, and a substrate support 104 for supporting a substrate 106. The linear PVD sources 102A and 102B are each configured to provide a respective directed stream of material flux (stream 108, or respective streams 108A and 108B, as depicted in FIG. 1) toward the substrate support 104 (and any substrate 106 disposed on the substrate support 104). The substrate support has a support surface to support the substrate 106 such that a working surface of the substrate 106 to be deposited on is exposed to the directed stream 108 of material flux. The stream 108 of material flux provided by the linear PVD source 102 has a width greater than that of the substrate support 104 (or at least greater than a substrate 106 disposed on the substrate support 104), measured at a position corresponding to the support surface or substrate position. The stream 108 of material flux has a linear elongate axis corresponding to the width of the stream 108 of material flux (e.g., the stream 108 is narrower in a dimension perpendicular to the elongate axis in the plane of the support surface or substrate positioned thereon).

The substrate support 104 and the linear PVD source 102 are configured to move linearly with respect to each other along an axis normal to a plane of the support surface of the substrate support 104 (e.g., normal to the plane of a substrate supported on the substrate support 104), as indicated by axis 110. The relative motion can be accomplished by moving either or both of the linear PVD source 102 or the substrate support 104. In some embodiments, the linear PVD source 102 may be fixed and the substrate support 104 can be configured to move. Optionally, the substrate support 104 may additionally be configured to rotate (for example, within the plane of the support surface), as indicated by arrows 112.

The linear PVD source 102 includes target material to be sputter deposited on the substrate. In some embodiments, the target material can be, for example, a metal, such as titanium, or the like, suitable for depositing titanium (Ti) or titanium nitride (TiN) on the substrate 106. In some embodiments, the target material can be, for example, silicon, or a silicon-containing compound, suitable for depositing silicon (Si), silicon nitride (SiN), silicon oxynitride (SiON), or the like on the substrate 106. Other materials may suitably be used as well in accordance with the teachings provided herein. In general, the target material can be any material typically used in thin film fabrication via physical vapor deposition. The linear PVD source 102 further includes, or is coupled to, a power source to provide suitable power for forming a plasma proximate the target material and for sputtering atoms off of the target material. The power source can be either or both of a DC or an RF power source.

Unlike an ion beam or other ion source, the linear PVD source 102 is configured to provide mostly neutrals and few ions of the target material. As such, a plasma may be formed having a sufficiently low density to avoid ionizing too many of the sputtered atoms of target material. For example, for a 300 mm diameter wafer as the substrate, about 1 to about 20 kW of DC or RF power may be provided. The power or power density applied can be scaled for other size substrates. In addition, other parameters may be controlled to assist in providing mostly neutrals in the stream 108 of material flux. For example, the pressure may be controlled to be sufficiently low so that the mean free path is longer than the general dimensions of an opening of the linear PVD source 102 through which the stream of material flux passes toward the substrate support 104 (as discussed in more detail below). In some embodiments, the pressure may be controlled to be about 0.5 to about 5 millitorr.

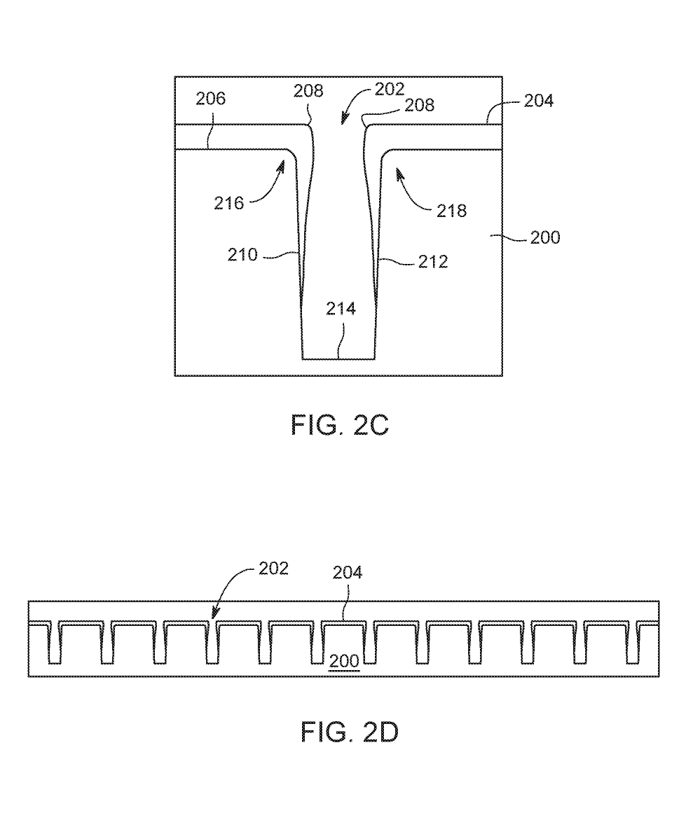

The methods and embodiments disclosed herein advantageously enable deposition of materials with a shaped profile, or in particular, with an asymmetric profile with respect to a given feature on a substrate, while maintaining overall deposition and shape uniformity across all features on a substrate. For example, FIG. 2A depicts a schematic side view of a substrate 200 including a feature 202 having a layer of material 204 deposited thereon in accordance with at least some embodiments of the present disclosure. The feature 202 can be a trench, a via, or dual damascene feature, or the like. In addition, the feature 202 can protrude from the substrate 200 rather than extend into the substrate 200. The material 204 is deposited not just atop a top surface 206 of the substrate 200 (e.g., the field region), but also within or along at least portions of the feature 202 as well. However, the material 204 is deposited to a greater thickness on a first side 210 of the feature as compared to an opposing second side 212 of the feature (as depicted by portion 208 of material). In some embodiments, and depending upon the incoming angle of the stream of material flux, the material 204 can be deposited on a bottom 214 of the feature. In some embodiments, and as depicted in FIG. 2A, little or no of the material 204 is deposited on a bottom 214 of the feature. In some embodiments, additional material 204 is deposited particularly near an upper corner 216 of the first side 210 of the feature 202, as compared to an opposite upper corner 218 of the second side 212 of the feature 202.

As shown in FIG. 2B, which is a schematic side view of the substrate 200 having a plurality of features having a layer of material deposited thereon in accordance with at least some embodiments of the present disclosure, the material 204 is deposited relatively uniformly across a plurality of features 202 formed in the substrate 200. As shown in FIG. 2B, the shape of the deposited material 204 is substantially uniform from feature to feature across the substrate 200, but is asymmetric within any given feature 202. Thus, embodiments in accordance with the present disclosure advantageously provide controlled/uniform angular deposition of material on a substrate with a substantially uniform amount of material deposited on a field region of the substrate.

In some embodiments, for example where the substrate support 104 is configured to rotate in addition to moving linearly with respect to the linear PVD source 102, different profiles of material deposition can be provided. For example, FIG. 2C depicts a schematic side view of the substrate 200 including the feature 202 having a layer of material 204 deposited thereon in accordance with at least some embodiments of the present disclosure. As described above with respect to FIGS. 2A-2B, the material 204 is deposited not just atop a top surface 206 of the substrate 200 (e.g., the field region), but also within or along at least portions of the feature 202 as well. However, in embodiments consistent with FIG. 2C, the material 204 is deposited to a greater thickness on both the first side 210 of the feature as well as the opposing second side 212 of the feature 202 (as depicted by portion 208 of material) as compared to the bottom 214 of the feature 202. In some embodiments, and depending upon the incoming angle of the stream of material flux, the amount of materials deposited on lower portions of the sidewall and the bottom 214 of the feature can be controlled. However, as depicted in FIG. 2C, little or no material is deposited on the bottom 214 of the feature 202 (as well as on the lower portion of the sidewalls proximate the bottom 214).

As shown in FIG. 2D, which is a schematic side view of the substrate 200 having a plurality of the features 202 having a layer of material deposited thereon in accordance with at least some embodiments of the present disclosure, the material 204 is deposited relatively uniformly across the plurality of features 202 formed in the substrate 200. As shown in FIG. 2D, the shape of the deposited material 204 is substantially uniform from feature to feature across the substrate 200, but with a controlled material profile within any given feature 202. Thus, embodiments in accordance with the present disclosure advantageously provide controlled/uniform angular deposition of material on a substrate with a substantially uniform amount of material deposited on a field region of the substrate.

Although the above description of FIGS. 2A-2D refer to the feature 202 having sides (e.g., a first side 210 and a second side 212), the feature 202 can be circular (such as a via). In such cases where the feature 202 is circular, although the feature 202 may have a singular sidewall, the first side 210 and second side 212 can be arbitrarily selected/controlled based upon the orientation of the substrate 106 with respect to the linear axis of movement of the substrate support 104 and direction of the stream of material flux from the linear PVD source 102. Moreover, in embodiments where the substrate support 104 can rotate, the first side 210 and second side 212 can change, or be blended, dependent upon the orientation of the substrate 106 during processing.

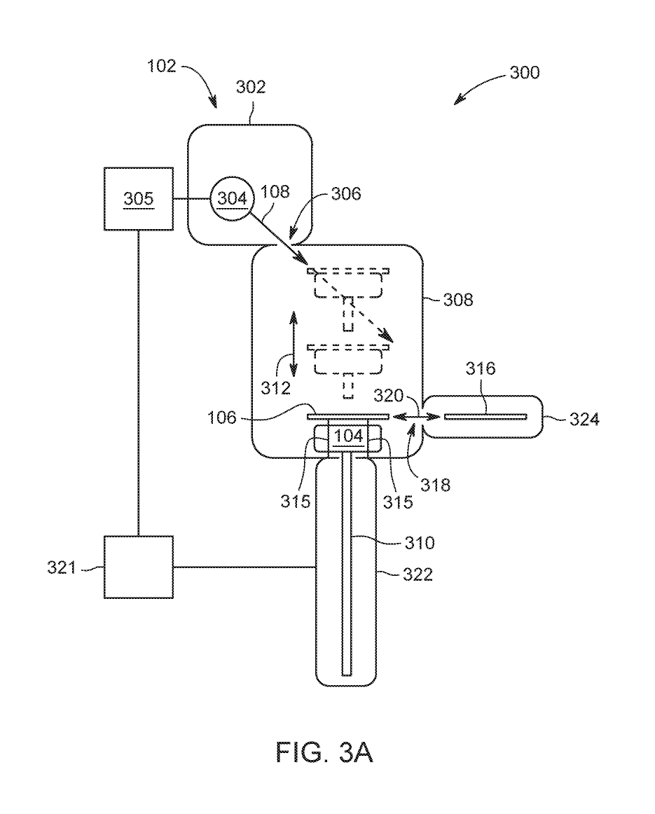

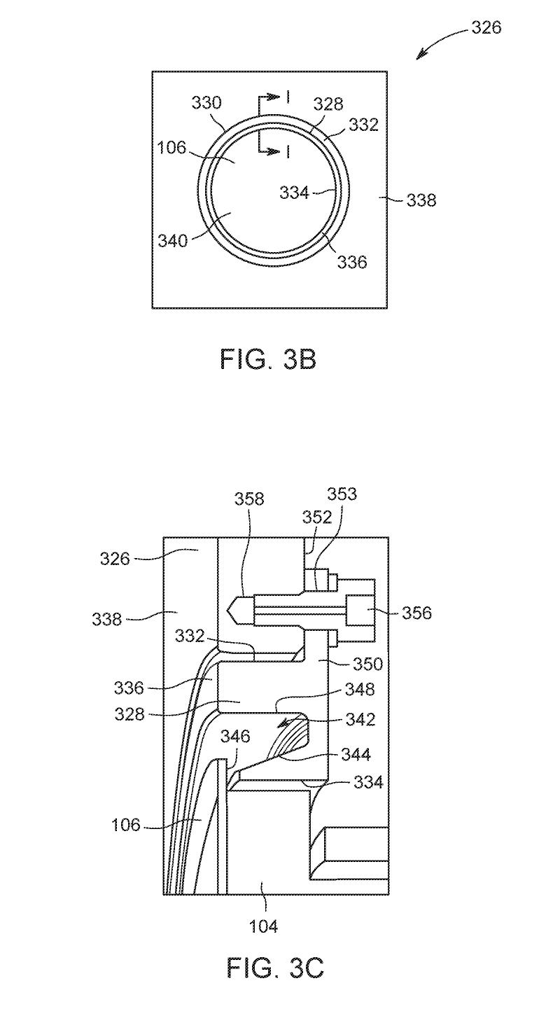

The above apparatus 100 can be implemented in numerous ways, and several non-limiting embodiments are provided herein in FIG. 3A through FIG. 7. While different Figures may discuss different features of the apparatus 100, combinations and variations of these features may be made in keeping with the teachings provided herein. In addition, although the Figures may show an apparatus having a particular orientation, such orientations are examples and not limiting of the disclosure. For example, any configuration can be rotated or oriented differently than as shown on the page. FIG. 3A is a schematic side view of an apparatus 300 for physical vapor deposition in accordance with at least some embodiments of the present disclosure. The apparatus 300 is an exemplary implementation of the apparatus 100 and discloses several exemplary features.

As depicted in FIG. 3A, the linear PVD source 102 may include a chamber or housing 302 having an interior volume. A target 304 of source material to be sputtered is disposed within the housing 302. The target 304 is generally elongate and can be, for example, cylindrical or rectangular. For example, the target 304 depicted in FIG. 3A is cylindrical. However, the target 304 can also be a rectangular target having, for example, a planar rectangular face of target material to be sputtered. The target 304 size can vary depending upon the size of the substrate 106 and the configuration of the processing chamber. For example, for processing a 300 mm diameter semiconductor wafer, the target 304 can be between about 100 to about 200 mm in width or diameter, and can have a length of about 400 to about 600 mm. The target 304 can be stationary or movable, including rotatable along the elongate axis of the target 304.

The target 304 is coupled to a power source 305. A gas supply (not shown) may be coupled to the interior volume of the housing 302 to provide a gas, such as an inert gas (e.g., argon) or nitrogen (N₂) suitable for forming a plasma within the interior volume when sputtering material from the target 304 (creating the stream 108 of material flux). The housing 302 is coupled to a deposition chamber 308 containing the substrate support 104. A vacuum pump can be coupled to an exhaust port (not shown) in at least one of the housing 302 or the deposition chamber 308 to control the pressure during processing.

An opening 306 couples the interior volumes of the housing 302 and the deposition chamber 308 to allow the stream 108 of material flux to pass from the housing 302 into the deposition chamber 308, and onto the substrate 106. As discussed in more detail below, the position of the opening 306 with respect to the target 304 as well as the dimensions of the opening 306 can be selected or controlled to control the shape and size of the stream 108 of material flux passing though the opening 306 and into the deposition chamber 308. For example, the length of the opening 306 is wide enough to allow the stream 108 of material flux to be wider than the substrate 106. In addition, the width of the opening 306 may be controlled to provide an even deposition rate along the length of the opening 306 (e.g., a wider opening may provide greater deposition uniformity, while a narrower opening may provide increased control over the angle of impingement of the stream 108 of material flux on the substrate 106). In some embodiments, a plurality of magnets may be positioned proximate the target 304 to control the position of the plasma with respect to the target 304 during processing. The deposition process can be tuned by controlling the plasma position (e.g., via the magnet position), and the size and relative position of the opening 306.

The housing 302 can include a liner of suitable material to retain particles deposited on the liner to reduce or eliminate particulate contamination on the substrate 106. The liner can be removable to facilitate cleaning or replacement. Similarly, a liner can be provided to some or all of the deposition chamber 308, for example, at least proximate the opening 306. The housing 302 and the deposition chamber 308 are typically grounded.

In the embodiment depicted in FIG. 3A the linear PVD source 102 is stationary and the substrate support 104 is configured to move linearly. The substrate 106 may be moved linearly along an axis perpendicular to a plane of the support surface of the substrate support 104 (e.g., perpendicular to the plane of the substrate surface). For example, the substrate support 104 is coupled to a shaft 310 that can move linearly back and forth (e.g., closer to and further from the linear PVD source 102) sufficiently to allow the stream 108 of material flux to impinge upon desired portions of the substrate 106, such as the entire substrate 106. A position control mechanism 322, such as an actuator, motor, drive, or the like, controls the position of the substrate support 104, for example, via the shaft 310.

The substrate support 104 is movable at least between a first position, closest to the linear PVD source 102 and a second position, further from the linear PVD source 102. The first position is configured such that, in operation, the stream 108 of material flux is proximate a first side of the substrate 106. In the first position, the stream 108 of material flux can either miss the substrate 106 or can impinge upon at least the working surface of the substrate 106 along the first side (e.g., the first side 210) of the substrate 106. The second position is configured such that, in operation, the stream 108 of material flux is proximate a second side (e.g., the second side 212) of the substrate 106, opposite the first side. In the second position, the stream 108 of material flux can either miss the substrate 106 or can impinge upon at least the working surface of the substrate 106 along the second side of the substrate 106. The first and second positions are configured such that motion between the two positions will cause the stream 108 of material flux to move across the substrate 106 from the first side to the second side, thus impinging upon the entire working surface of the substrate 106 over the course of a single scan from the first position to the second position (or from the second position to the first position).

The inventors have observed that the deposition rate of the material on the substrate varies with the distance of the substrate 106 from the linear PVD source 102. Specifically, the deposition rate on the substrate 106 drops as the distance from the substrate 106 to the linear PVD source 102 increases. In particular, the inventors have observed that the deposition rate on the substrate 106 drops proportionately with the square of the distance to the linear PVD source 102.

To compensate for the changing deposition rate, the inventors have observed that the deposition rate can be controlled by the power supplied to the target 304 or by control of the amount of time that the substrate 106 is exposed to the stream of material flux. The compensation can normalize the deposition of material across the entire working surface of the substrate 106 to be more uniform. As such, a controller 321 is provided and is operatively coupled to the position control mechanism 322, to the power source 305, or to both the position control mechanism 322 and the power source 305. The controller 321 includes a central processing unit (CPU), support circuits, and a computer readable medium (e.g., a nontransitory computer readable storage medium), or memory. The computer readable storage medium can be configured to store instructions that when executed by the controller can perform a method for performing physical vapor deposition on a substrate (e.g., the substrates 106, 200), as will be described in greater detail below.

In some embodiments, the controller 321 is configured to control the amount of power supplied by the power source 305 to the target 304 based upon the position of the substrate support 104. For example, the power level can be increased as the substrate support 104 moves further from the linear PVD source 102 and decreased as the substrate support 104 moves closer to the linear PVD source 102. The control over the power supplied can be continuous, with the power level being continuously adjusted based upon substrate support position, or stepwise, with the power level changing at predetermined increments corresponding to different substrate support 104 positions.

Alternatively or in combination, in some embodiments, the controller 321 is configured to variably control the speed of the substrate support 104 (via control of the position control mechanism 322) based upon the position of the substrate support 104. For example, the rate of movement of the substrate support 104 can be decreased as the substrate support 104 moves further from the linear PVD source 102 (to increase residence time in the stream and thus increase the amount of material deposited on the substrate 106) and decreased as the substrate support 104 moves closer to the linear PVD source 102 (to decrease residence time in the stream and thus decrease the amount of material deposited on the substrate 106). The control over the substrate support 104 movement speed can be continuous, with the speed being continuously adjusted based upon substrate support 104 position, or stepwise, with the seed changing at predetermined increments corresponding to different substrate support 104 positions.

Optionally, the substrate support 104 can also be configured to rotate within the plane of the support surface, such that a substrate disposed on the substrate support 104 can be rotated. A rotation control mechanism, such as an actuator, motor, drive, or the like, controls the rotation of the substrate support 104 independent of the linear position of the substrate support 104. Accordingly, the substrate support 104 can be rotated while the substrate support 104 is also moving linearly through the stream 108 of material flux during operation. Alternatively, the substrate support 104 can be rotated between linear scans of the substrate support 104 through the stream 108 of material flux during operation (e.g., the substrate support 104 can be moved linearly without rotation, and rotated while not moving linearly).

In addition, the substrate support 104 can move to a position for loading and unloading of substrates into and out of the deposition chamber 308. For example, in some embodiments, a transfer chamber 324, such as a load lock, may be coupled to the deposition chamber 308 via a slot or opening 318. A substrate transfer robot 316, or other similar suitable substrate transfer device, can be disposed within the transfer chamber 324 and movable between the transfer chamber 324 and the deposition chamber 308, as indicated by arrows 320, to move substrates into and out of the deposition chamber 308 (and onto and off of the substrate support 104). In some embodiments, and as depicted in FIG. 3A, the position for loading and unloading of substrates into and out of the deposition chamber 308 can be lower than the second position (or further from the linear PVD source 102). Lift pins 315 may be provided and configured to lift the substrate 106 from the substrate support 104 when in the loading and unloading position.

Depending upon the configuration of the substrate support 104, and in particular of the support surface of the substrate support 104 (e.g., vertical, horizontal, or angled), the substrate support 104 may be configured appropriately to retain the substrate 106 during processing. For example, in some embodiments, the substrate 106 may rest on the substrate support 104 via gravity. In some embodiments, the substrate 106 may be secured onto the substrate support 104, for example, via a vacuum chuck, an electrostatic chuck, mechanical clamps, or the like. Substrate guides and alignment structures may also be provided to improve alignment and retention of the substrate 106 on the substrate support 104.

FIGS. 3B-3C respectively depict schematic top and isometric cross-sectional views of a substrate support and deposition structure of an apparatus for physical vapor deposition in accordance with at least some embodiments of the present disclosure. FIG. 3C is an isometric cross-sectional view of the substrate support and deposition structure taken along line I-I in FIG. 3B.

As shown in FIGS. 3B-3C, a deposition structure 326 may be disposed around the substrate 106 and the substrate support 104 within the deposition chamber 308. For example, the deposition structure 326 may be coupled to the substrate support 104. In some embodiments, the deposition structure 326 and a front surface of the substrate 106 form a common planar surface. The deposition structure 326 reduces deposits or particles from accumulating on the edge and backside of the substrate 106 during the scanning of the substrate 106. Furthermore, use of the deposition structure 326 reduces deposits or particles from accumulating on the substrate support 104 and hardware and equipment in the vicinity of the substrate support 104. In some embodiments, a voltage source (not shown) may be coupled to a portion of the deposition structure 326 to apply a charge to a portion of the deposition structure 326. In some embodiments, the voltage source may be used to apply a voltage or charge to a removable structure 328 associated with the deposition structure 326. Although the stream of material flux comprises mostly neutrals, applying a charge to the portion of the deposition structure 326 or the removable structure 328 may further reduce deposits or particles that accumulate on the edge and backside of the substrate 106 during the scanning of the substrate 106 due to any ionized particles.

In some embodiments, the deposition structure 326 includes a removable structure 328 disposed in an opening 330 of the deposition structure 326. The removable structure 328 can have a shape that corresponds to the substrate 106. For example, in embodiments where the substrate 106 is a circular substrate, such as a semiconductor wafer, the removable structure 328 is a removable ring structure. As depicted in FIGS. 3C-3D, the substrate 106 is exposed through the opening 330.

The removable structure 328 has an outside edge surface 332 and an inside edge surface 334. A circumference of the inside edge surface 334 is greater than a circumference of the substrate support 104. Furthermore, in some embodiments, the removable structure 328 has an exterior surface 336 aligned with a front surface 338 of the deposition structure 326. Furthermore, in some embodiments, a front surface 340 of the substrate 106 may be aligned with the front surface 338 of the deposition structure 326 and the exterior surface 336 of the removable structure 328. Therefore, in some embodiments, the exterior surface 336 of the removable structure 328, the front surface 338 of the deposition structure 326, and the front surface 340 of the substrate 106 form a planar surface. In some embodiments, the exterior surface 336 is not aligned with the front surface 338 of the deposition structure 326 and/or the front surface 340 of the substrate 106.

As depicted in FIG. 3C, the removable structure 328 includes a groove 342. The groove 342 may be formed in at least a portion of a circumference of the removable structure 328. In some embodiments, the groove 342 is formed in the entire circumference of the removable structure 328. The groove 342 may include an angled surface 344 functional to direct the particles associated with the stream 108 of material flux away from a backside 346 of the substrate 106. Moreover, the angled surface 344 is functional to direct particles associated with the stream 108 of material flux away from the substrate support 104. In some embodiments, particles associated with the stream 108 of material flux may be directed by the angled surface 344 toward a surface 348 associated with the groove 342. The groove 342 may be formed having a shallower or deeper depth than shown in FIG. 3C. Furthermore, while the surface 348 is illustrated as being straight, the surface 348 may alternatively be formed at an angle similar to the angled surface 344.

The removable structure 328 can include a ledge 350. The ledge 350 may be in contact with a backside 352 of the deposition structure 326. In some embodiments, the ledge 350 is removably press fit against the deposition structure 326, on the backside 352 of the deposition structure 326.

In some embodiments, the ledge 350 is coupled to the deposition structure 326, on the backside 352 of the deposition structure 326. For example, the removable structure 328 may include one or more through holes 353. In some embodiments, a plurality of through holes 353 are disposed in the ledge 350. The plurality of through holes 353 may receive a retainer element 356, such as a fastener, screw, or the like. Each of the retainer elements 356 may be received by a hole 358 in the deposition structure 326. Therefore, the deposition structure 326 may include a plurality of the holes 358. In another embodiment, the holes 358 may be through holes so that the retainer elements 356 may be inserted from the front surface 338 of the deposition structure 326 and retainably attached to the ledge 350 using a nut, fastener or threads.

The substrate 106 plane structure having a removable ring is advantageously straightforward to maintain. Specifically, advantageously, rather than removing the entire substrate 106 plane structure when preventive maintenance is required, the removable ring can be removed to complete the required preventative maintenance. Furthermore, because the substrate 106 plane structure and the removable ring pieces advantageously provide a modular unit, the costs associated with maintaining and replacing the modular unit may be advantageously reduced compared to maintaining and replacing conventional substrate plane structures formed as one contiguous unit. In addition, advantageously, removable rings may be made from different materials compared to the remainder of the substrate 106 plane structure. For example, use of particular material types for the removable rings may advantageously mitigate accumulation of deposits and particles on the edge of the wafer.

In embodiments of a PVD apparatus as disclosed herein, the general angle of incidence of the stream 108 of material flux can be controlled or selected to facilitate a desired deposition profile of material on the substrate 106. In addition, the general shape of the stream 108 of material flux can be controlled or selected to control the deposition profile of material deposited on the substrate 106. In some embodiments, material can be deposited on a top surface of the substrate 106 and a first sidewall of a feature (e.g., the feature 202) on the substrate 106 (e.g., substantially as depicted in FIGS. 2A and 2D). In some embodiments, depending upon the deposition angle, material can further be deposited on a bottom surface of the feature. In some embodiments, depending upon the deposition angle, material can further be deposited on an opposing sidewall surface of the feature, with greater deposition on a first sidewall as compared to the opposing sidewall of the feature.

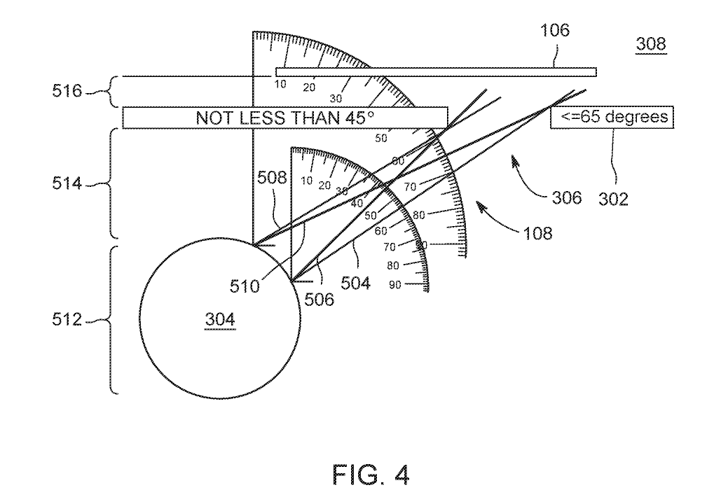

For example, FIG. 4 is a schematic side view of an apparatus for physical vapor deposition illustrating material deposition angles in accordance with at least some embodiments of the present disclosure. The position of the target 304 within the housing 302 with respect to the opening 306 coupling the housing 302 to the deposition chamber 308 defines a general angle of incidence of the stream 108 in a plane orthogonal to the length of the opening 306 (e.g., in the plane of the page, where the opening 306 runs in a direction into and out of the page). However, the general angle of incidence is not the angle of incidence of all particles in the stream 108 of material flux, since the particles can come from different locations on the target and can generally travel through the opening 306 along a line of sight from the location on the target 304 where the particle originated.

For example, to control the size of the stream 108 of material flux, in addition to the angle of incidence, several parameters can be predetermined, selected, or controlled. For example, a diameter 512 or width of the target 304 can be predetermined, selected, or controlled. In addition, a first working distance 514 from the target 304 to the sidewall of the housing 302 containing the opening 306, can be predetermined, selected, or controlled. A second working distance 516 from the opening 306 to the substrate 106 can also be predetermined, selected, or controlled. Lastly, the size of the opening 306 can be predetermined, selected, or controlled. Taking these parameters into account, the minimum and maximum angles of incidence can be predetermined, selected, or controlled as shown in FIG. 4.

For example, with a given target diameter 512 of target 304, working distance 514, and second working distance 516, the size of the opening 306 can be set to control a width of the stream 108 of material flux that passes through the opening 306 an impinges upon the substrate 106. For example, the opening 306 (and other parameters discussed above) can be set to control the minimum and maximum angles of incidence of material from the stream 108 of material flux. For example, lines 506 and 504 represent possible paths of material from a first portion of the target 304 that can pass through the opening 306. Lines 508 and 510 represent possible paths of material from a second portion of the target 304 that can pass through the opening 306. The first and second portions of the target 304 represent the maximum spread of materials with line of sight paths to the opening 306. The overlap of paths of materials that can travel via line of sight through the opening 306 are bounded by lines 506 and 510, which represent the minimum and maximum angles of incidence of material from the stream 108 of material flux that can pass through the opening 306 and deposit on the substrate 106. The angles of 45 degrees and 65 degrees are illustrative. For example, the angle of impingement may generally range between about 10 to about 65 degrees, or more.

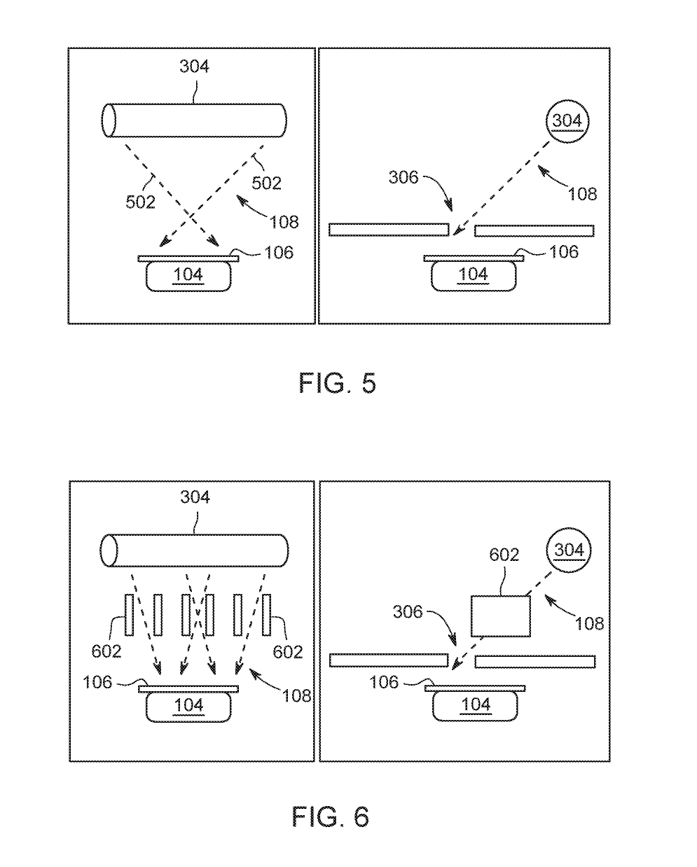

The above discussion with respect to FIG. 4 refers to the shape and angles of incidence of materials from the stream 108 of material flux along planes orthogonal to the axial length of the opening 306 (e.g., side views of the stream 108 of material flux). FIG. 5 depicts schematic top and side views of an apparatus for physical vapor deposition illustrating top and side view of material deposition angles in accordance with at least some embodiments of the present disclosure. As depicted in FIG. 5, right panel, a side view of the stream 108 of material flux is shown, which corresponds to FIG. 4 above. FIG. 5, left panel, depicts a top view showing the stream 108 of material flux from a top view, parallel to the axial length of the target 304 (and opening 306), referred to herein as in a lateral direction (e.g., side to side along the axial length of the target). As shown in the top view of FIG. 5, left panel, the angles 502 of incidence of material from the stream 108 of material flux can vary greatly and also are not controlled as the angles are along the side dimensions discussed above.

In some embodiments, the lateral angles of incidence can also be controlled. For example, FIG. 6 depicts schematic top and side views of an apparatus for physical vapor deposition illustrating material deposition angles in accordance with at least some embodiments of the present disclosure. The teachings of FIG. 6 can be incorporated in any of the embodiments disclosed herein. As depicted in FIG. 6, physical structure such as baffles, or collimator 602, can be interposed between the target 304 and the opening 306 such that the stream 108 of material flux travels through the structure (e.g., collimator 602). Any materials with an angle to great to pass through the structure will be blocked from passing through the opening 306, thus limiting the permitted angular range of materials passing through the opening 306.

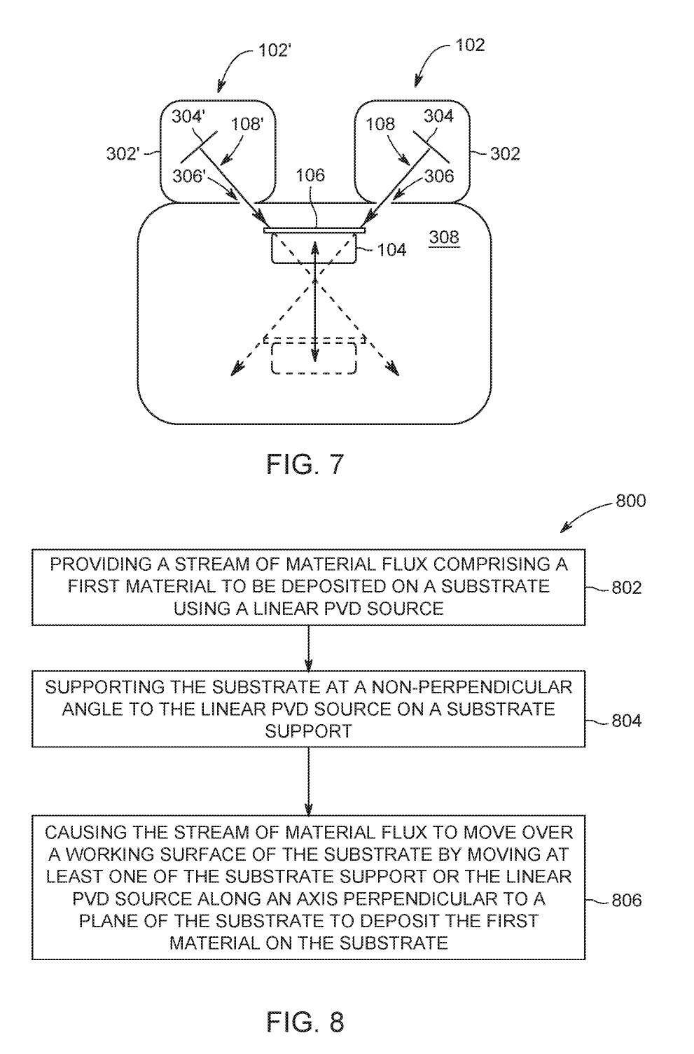

Combinations and variations of the above embodiments include apparatus having more than one target to facilitate deposition at multiple angles. For example, FIG. 7 is a schematic side view of an apparatus for physical vapor deposition in accordance with at least some embodiments of the present disclosure. As depicted in FIG. 7, two linear PVD sources 102, 102′ may be provided, such that targets 304, 304′ can have respective streams 108, 108′ of material flux that are separately directed through respective openings 306, 306′ to impinge of the substrate 106. The target materials can be the same material or different materials. In addition, process gases provided to the separate linear PVD sources 102, 102′ can be the same or different. The size of the targets 304, 304′, location of the targets 304, 304′, location and size of the openings 306, 306′, can be independently controlled to independently control the impingement of materials from each stream 108, 108′ of material flux onto the substrate 106.

The relative angles of the targets 304, 304′, and thus the direction of the streams 108, 108′ of material flux are illustrative and other angles can be chosen independently, including in directions such that the targets 304, 304′ are not parallel to each other.

FIG. 8 is a flowchart of a method 800 for performing physical vapor deposition in accordance with at least some embodiments of the present disclosure. At 802, the linear PVD source (e.g., the linear PVD source 102) can be used to provide a stream of material flux (e.g., the stream 108) including a material (e.g., the material 204) and to deposit the material on a substrate (e.g., the substrate 106), which can be disposed on the support surface of the substrate support (e.g., the substrate support 104) at 804. At 806, the stream of material flux passes into the deposition chamber (e.g., the deposition chamber 308) through the opening (e.g., the opening 306) between the linear PVD source and the deposition chamber. Optionally, the range of angles of travel of the material within the elongate dimension of the stream can be limited (e.g., as disclosed in FIG. 6).

Continuing at 806 the substrate support can be moved (e.g., along an axis that is perpendicular to a plane of the support surface of the substrate) linearly from a first position (for example, where the stream of material flux is proximate a first side of the substrate), through the stream of material flux to a second position (for example, where the stream of material flux is proximate a second side of the substrate opposite the first side). For example, the first position can position the substrate completely out of the stream of material flux, or at least a portion of the stream of material flux. Moreover, the second position can also position the substrate completely out of the stream of material flux, or at least a portion of the stream of material flux. Continuing at 806, the amount of deposition of material on the substrate depends upon the deposition rate and the rate of speed of the linear movement of the substrate through the stream of material flux. The substrate can pass through the stream of material flux once (e.g., move from the first position to the second position once) or multiple times (e.g., move from the first position to the second position, then move from the second position to the first position, etc.) in order to deposit a desired thickness of material on the substrate. Optionally, the substrate can be rotated between passes (e.g., after reaching the first position or the second position at the end of linear movement) or while passing through the stream of material flux (e.g., at the same time as the linear movement from the first position to the second position).

In embodiments where two streams of material flux are provided (e.g., as shown in FIG. 7), the streams can be alternated or provided simultaneously. In addition, the orientation of the substrate can be rotationally fixed or variable. For example, in some embodiments, the two streams of material flux can alternately provide the same material or different materials to be deposited asymmetrically on the substrate as shown in FIGS. 2A-2B. The substrate can be rotationally fixed while the first stream of material flux is provided in a first pass through the first stream of material flux. The substrate can then be rotated 180 degrees and subsequently be rotationally fixed while the second stream of material flux is provided in a first pass through the second stream of material flux. If desired, after completion of the first pass through the second stream of material flux, the substrate can again be rotated 180 degrees and then held rotationally fixed in a second pass through the first stream of material flux. The rotation of the substrate and passes through either the first or the second streams of material flux can continue until a desired thickness of material is provided. In cases where the first and second streams of material flux provide different materials to be deposited, the rate of movement of the substrate support can be the same or different when passing through the first stream of material flux as compared to passing through the second stream of material flux.

In some embodiments, the substrate can be rotated continuously while passing through the first or the second stream of material flux (e.g., at the same time as the linear movement from the first position to the second position or from the second position to the first position) to achieve a deposition profile similar to that shown in FIGS. 2C-2D.

While the foregoing is directed to embodiments of the present disclosure, other and further embodiments of the disclosure may be devised without departing from the basic scope thereof.

1. An apparatus for physical vapor deposition (PVD), comprising:
a linear PVD source to provide a stream of material flux comprising material to be deposited on a substrate; and
a substrate support having a support surface to support the substrate at a non-perpendicular angle to the linear PVD source,
wherein the substrate support and linear PVD source are movable with respect to each other along an axis that is perpendicular to a plane of the support surface of the substrate support sufficiently to cause the stream of material flux to move over a working surface of the substrate disposed on the substrate support during operation.

2. The apparatus of claim 1, wherein the substrate support can rotate within the plane of the support surface.

3. The apparatus of claim 1, further comprising:
a second linear PVD source to provide a second stream of material flux comprising material to be deposited on the substrate at a non-perpendicular angle to the plane of the support surface.

4. The apparatus of claim 1, wherein the substrate support is movable from a first position, which is closest to the linear PVD source, to a second position, which is further from the linear PVD source.

5. The apparatus of claim 4, wherein in the first position the stream of material flux is proximate a first side of the substrate, such that in the first position the stream of material flux can at least one of miss the substrate or impinge upon at least the working surface of the substrate along the first side of the substrate.

6. The apparatus of claim 4, wherein in the second position the stream of material flux is proximate a second side of the substrate opposite the first side, such that in the second position the stream of material flux can at least one of miss the substrate or impinge upon at least the working surface of the substrate along the second side of the substrate.

7. The apparatus of claim 4, wherein the first position and the second position are configured such that, in operation, motion between the first position and the second position causes the stream of material flux to move across the substrate from a first side of the substrate to an opposite second side of the substrate.

8. The apparatus of claim 1, wherein an opening couples an interior volume of a housing of the apparatus and a deposition chamber of the apparatus to allow the stream of material flux to pass from the housing into the deposition chamber and onto the substrate.

9. The apparatus of claim 8, wherein the opening has a width that is wider than a width of the substrate.

10. A method for physical vapor deposition (PVD), comprising:
providing a stream of material flux comprising a first material to be deposited on a substrate using a linear PVD source;
supporting the substrate at a non-perpendicular angle to the linear PVD source on a substrate support; and
causing the stream of material flux to move over a working surface of the substrate by moving at least one of the substrate support or the linear PVD source along an axis perpendicular to a plane of the substrate to deposit the first material on the substrate.

11. The method of claim 10, further comprising rotating the substrate within the plane of the substrate using the substrate support.

12. The method of claim 10, further comprising:
depositing a second material on the substrate at a non-perpendicular angle to the plane of the substrate using a second linear PVD source configured to provide a second stream of material flux comprising the second material.

13. The method of claim 12, wherein the second material is the same as the first material.

14. The method of claim 12, wherein the second material is different from the first material.

15. The method of claim 10, further comprising moving the substrate support from a first position, which is closest to the linear PVD source, to a second position, which is further from the linear PVD source.

16. The method of claim 15, wherein in the first position the stream of material flux is proximate a first side of the substrate, such that in the first position the stream of material flux can at least one of miss the substrate or impinge upon at least the working surface of the substrate along the first side of the substrate.

17. The method of claim 15, wherein in the second position the stream of material flux is proximate a second side of the substrate opposite the first side, such that in the second position the stream of material flux can at least one of miss the substrate or impinge upon at least the working surface of the substrate along the second side of the substrate.

18. The method of claim 15, wherein the substrate moves between the first position and the second position such that the stream of material flux impinges upon an entire working surface of the substrate over a course of at least one of a single scan from the first position to the second position or from the second position to the first position.

19. A nontransitory computer readable storage medium having stored thereon instructions which when executed by a controller perform a method for physical vapor deposition (PVD), comprising:
providing a stream of material flux comprising a first material to be deposited on a substrate using a linear PVD source;
supporting the substrate at a non-perpendicular angle to the linear PVD source on a substrate support; and
causing the stream of material flux to move over a working surface of the substrate by moving at least one of the substrate support or the linear PVD source along an axis perpendicular to a plane of the substrate to deposit the first material on the substrate.

20. The nontransitory computer readable storage medium of claim 19, further comprising:
rotating the substrate support within the plane of the support surface.
